(19) United States
(12) Patent Application Publication
(10) Pub. No.: US 2024/0047772 A1
(43) Pub. Date: Feb. 8, 2024

(54) ELECTROCHEMICAL CELLS AND ELECTROCHEMICAL CELL STACKS WITH SERIES CONNECTIONS, AND METHODS OF PRODUCING, OPERATING, AND MONITORING THE SAME

(71) Applicant: 24M Technologies, Inc., Cambridge, MA (US)

(72) Inventors: Chad Alan HARTZOG, Columbus, IN (US); Mark YOUNG, Lapel, IN (US); Ryan Michael LAWRENCE, Cambridge, MA (US); Junzheng CHEN, Concord, MA (US); Naoki OTA, Lexington, MA (US)

(21) Appl. No.: 18/228,920

(22) Filed: Aug. 1, 2023

Related U.S. Application Data
(60) Provisional application No. 63/394,341, filed on Aug. 2, 2022.

(51) Int. Cl. H01M 10/48; H01M 50/531; G01R 31/392; G01R 31/3835

(52) U.S. Cl. CPC H01M 10/48; H01M 50/531; G01R 31/392; G01R 31/3835

(57) ABSTRACT

In some aspects, a method of monitoring health of an electrochemical cell can include measuring a first anode voltage at a first anode tab from the plurality of anode tabs and a second anode voltage at a second anode tab from the plurality of anode tabs; measuring a first cathode voltage at a first cathode tab from the plurality of cathode tabs and a second cathode voltage at a second cathode tab from the plurality of cathode tabs; and calculating a first sense voltage, the first sense voltage being a difference between the first cathode voltage and the first anode voltage. In some embodiments, a second sense voltage can be calculated, the second sense voltage being a difference between the second cathode voltage and the second anode voltage. In some embodiments, a difference between the first sense voltage and the second sense voltage can be calculated.

### CROSS-REFERENCE TO RELATED APPLICATIONS

This application claims priority to and the benefit of U.S. Provisional Patent Application No. 63/394,341 entitled, “Electrochemical Cells and Electrochemical Cell Stacks with Series Connections and Methods of Producing, Operating, and Monitoring the Same,” filed Aug. 2, 2022; the disclosure of which is incorporated herein by reference in its entirety.

### TECHNICAL FIELD

Embodiments described herein relate to electrochemical cells connected in series, and methods of producing, operating, and monitoring the same.

### BACKGROUND

In lithium-ion batteries containing a plurality of electrochemical cells electrically connected in series, it is desirable to monitor and balance the voltage of each electrochemical cell to optimize overall performance of the battery. The voltage of each electrochemical cell is monitored to assess state-of-health of the cell and to ensure that the voltage does not exceed set limits during charge and discharge of the cell. Because cell-to-cell variation exists, electrochemical cells are also periodically balanced, which involves removing electrical charge from or adding electrical charge to a cell to ensure voltage across cells do not significantly diverge from one another, as significant divergence in voltage would reduce performance of the battery. In a typical state-of-the-art lithium-ion battery, monitoring and balancing of an individual electrochemical cell are conducted through the same electrical connection points, thereby precluding the ability to monitor and balance the electrochemical cell simultaneously. Additionally, when sensing voltage through a connection point that is also carrying the system current, the measured voltage may have a voltage offset that is proportional to the system current flow. This voltage offset due to current flow may cause error that must be accounted for in filtering and monitoring algorithms. Furthermore, in electrochemical cells with large-area electrodes, intra-electrode voltage gradients may exist, which affect the voltage measured at a single reference point, thereby reducing the effectiveness of existing balancing and monitoring algorithms. Therefore, a mechanism by which electrochemical cells connected in series can be more accurately and efficiently monitored and balanced is needed.

### SUMMARY

Embodiments described herein relate to methods of producing, operating, and monitoring electrochemical cells connected in series. In some aspects, a method of operating an electrochemical cell included in an electrochemical cell stack having a plurality of electrochemical cells, each of the electrochemical cells included in the electrochemical cell stack including an anode material coupled to an anode current collector having a plurality of anode tabs, a cathode material coupled to a cathode current collector having a plurality of cathode tabs, and a separator disposed between the anode material and the cathode material, the method including: measuring an anode voltage difference between a first anode tab from the plurality of anode tabs and a second anode tab from the plurality of anode tabs of the electrochemical cell; measuring a cathode voltage difference between a first cathode tab from the plurality of cathode tabs and a second cathode tab from the plurality of cathode tabs of the electrochemical cell; and balancing the electrochemical cell relative to the other electrochemical cells included in the electrochemical cell stack based on at least the values of the anode voltage difference and the cathode voltage difference. In some aspects, a method of monitoring health of an electrochemical cell can include measuring a first anode voltage at a first anode tab from the plurality of anode tabs and a second anode voltage at a second anode tab from the plurality of anode tabs; measuring a first cathode voltage at a first cathode tab from the plurality of cathode tabs and a second cathode voltage at a second cathode tab from the plurality of cathode tabs; and calculating a first sense voltage, the first sense voltage being a difference between the first cathode voltage and the first anode voltage. In some embodiments, a second sense voltage can be calculated, the second sense voltage being a difference between the second cathode voltage and the second anode voltage. In some embodiments, a difference between the first sense voltage and the second sense voltage can be calculated.

In some aspects, an electrochemical cell can include an anode material coupled to an anode current collector; a cathode material coupled to a cathode current collector; a separator disposed between the anode material and the cathode material; a plurality of anode tabs electrically connected to the anode current collector such that a first anode voltage can be measured at a first anode tab from the plurality of anode tabs and a second anode voltage can be measured at a second anode tab from the plurality of anode tabs; and a plurality of cathode tabs electrically connected to the cathode current collector such that a first cathode voltage can be measured at a first cathode tab from the plurality of cathode tabs and a second cathode voltage can be measured at a second cathode tab from the plurality of cathode tabs. In some embodiments, the first cathode tab and the first anode tab extend from a proximal end of the electrochemical cell. In some embodiments, the second cathode tab extends from a first horizontal side of the electrochemical cell and the second anode tab extends from a second horizontal side of the electrochemical cell, the second horizontal side opposing the first horizontal side.

### BRIEF DESCRIPTION OF THE DRAWINGS

FIG. 1 is a block diagram of an electrochemical cell stack, according to an embodiment.

FIG. 2 is a block diagram of an electrochemical cell, according to an embodiment.

FIG. 3 shows an electrochemical cell, according to an embodiment.

FIG. 4 shows an electrochemical cell, according to an embodiment.

FIG. 5 is a schematic flow chart of a method of monitoring health of an electrochemical cell, according to an embodiment.

### DETAILED DESCRIPTION

Embodiments described herein relate to methods of producing, operating, and monitoring electrochemical cells. Some embodiments described herein can be used for monitoring electrochemical cells connected in series. In systems including multiple electrochemical cells connected in series, such as lithium-ion batteries, electrochemical cell voltage is typically monitored and balanced to optimize performance of the battery. The voltage of each electrochemical cell is monitored to assess the health of each electrochemical cell and to ensure that the voltage of each electrochemical cell does not exceed set limits during charge and discharge. Additionally, because electrochemical cells may vary from one another due to small variations in materials and manufacture, electrochemical cells can be periodically balanced to eliminate divergence of voltage between electrochemical cells, as divergence in voltage can reduce overall performance of the battery. In electrochemical cells having large-area electrodes, intra-electrode voltage gradients may exist, which can affect the voltage measured at any single reference point and complicate monitoring and balancing. In existing methods, (1) monitoring and balancing of an individual electrochemical cell are conducted through the same electrical connection points, which precludes the ability to monitor and balance the electrochemical cell simultaneously, and (2) intra-electrode voltage gradients are estimated through the use of complex algorithms, the accuracy of which may be impacted by various factors such as cell aging.

Embodiments described herein may address drawbacks of existing methods by including multiple locations at which the voltage of an electrochemical cell may be measured. In some embodiments, multiple anode tabs and multiple cathode tabs can be used to measure voltage of an electrochemical cell at different locations along the anode and cathode respectively, thereby allowing direct measurement of intra-electrode gradients rather than estimation of the intra-electrode gradient using algorithms. Additionally, inclusion of multiple anode tabs and multiple cathode tabs enables simultaneous monitoring and balancing of any one electrochemical cell, thereby decreasing steps necessary in production or operation of the battery. For example, balancing of the electrochemical cell voltage may be conducted through a first anode tab and a first cathode tab, while monitoring of the electrochemical cell may be conducted through a second anode tab and a second cathode tab. Independently monitoring the variation of the voltage, for example, with respect to current flow in the system, may enable additional diagnostic functions not available in current state-of-the-art systems. Additional anode tabs and/or cathode tabs as described herein can be utilized in both large format cells and smaller format cells as local connections for a battery management system (BMS) and eliminate the need for long connection wires. Thus, systems and methods described herein may provide additional advantages in terms of packaging and wire length, especially for large format cells. Additionally, inclusion of multiple anode and cathode tabs can provide additional path(s) for monitoring electrochemical cell(s) that is separate from the current path of the system. Monitoring voltage at various points throughout cells or electrodes can be an important aspect of building an energy storage system. Current cell algorithms assume the electrochemical cell is essentially uniform and functions as a homogeneous entity. Identifying differences in voltage gradients or inflection points can help identify problematic cells or electrodes. Identifying these faulty elements during production or even during operation can significantly limit the downtime of the energy storage system during repair or replacement.

Embodiments described herein can include algorithms to detect cell level failure, internal shorts, and other failure modes using sensors. Sensing can be used to sense or determine cell voltage, temperature, current, module level voltage, module level temperature, module level current, pack level voltage, pack level temperature, and/or pack level current. Algorithms can then be used to diagnose the functional status of each cell in the system. In some cases, sensing can be accomplished via a BMS, test system sensing, secondary sensing systems, or any combination thereof. Safety systems can include area temperature (hot spot), fire detection, smoke detection, hydrogen detection, carbon monoxide (CO) detection, carbon dioxide (CO₂) detection, volatile organic compound (VOC) detection, or other detection methods to ensure the systems are not damaged or to prevent damage to the system, batteries and facilities during formation. Safety systems can include fire suppression systems to prevent facility damage, active venting systems to prevent facility damage and personal injury, and protection systems to provide propagation protection between cells, modules, and/or battery packs under formation.

In some embodiments, electrodes described herein can include conventional solid electrodes. In some embodiments, the solid electrodes can include binders. In some embodiments, electrodes described herein can include semi-solid electrodes. Semi-solid electrodes described herein can be made: (i) thicker (e.g., greater than 100 μm—up to 2,000 μm or even greater) than conventional electrodes due to the reduced tortuosity and higher electrical conductivity of the semi-solid electrode, (ii) with higher loadings of active materials, and (iii) with a simplified manufacturing process utilizing less equipment. These relatively thick semi-solid electrodes decrease the volume, mass and cost contributions of inactive components with respect to active components, thereby enhancing the commercial appeal of batteries made with the semi-solid electrodes. In some embodiments, the semi-solid electrodes described herein are binderless and/or do not use binders that are used in conventional battery manufacturing. Instead, the volume of the electrode normally occupied by binders in conventional electrodes, is now occupied by: 1) electrolyte, which has the effect of decreasing tortuosity and increasing the total salt available for ion diffusion, thereby countering the salt depletion effects typical of thick conventional electrodes when used at high rate, 2) active material, which has the effect of increasing the charge capacity of the battery, or 3) conductive additive, which has the effect of increasing the electronic conductivity of the electrode, thereby countering the high internal impedance of thick conventional electrodes. The reduced tortuosity and a higher electronic conductivity of the semi-solid electrodes described herein, results in superior rate capability and charge capacity of electrochemical cells formed from the semi-solid electrodes. Since the semi-solid electrodes described herein, can be made substantially thicker than conventional electrodes, the ratio of active materials (i.e., the semi-solid cathode and/or anode) to inactive materials (i.e., the current collector and separator) can be much higher in a battery formed from electrochemical cell stacks that include semi-solid electrodes relative to a similar battery formed form electrochemical cell stacks that include conventional electrodes. This substantially increases the overall charge capacity and energy density of a battery that includes the semi-solid electrodes described herein.

In some embodiments, the electrode materials described herein can be a flowable semi-solid or condensed liquid composition. In some embodiments, the electrode materials described herein can be binderless or substantially free of binder. A flowable semi-solid electrode can include a suspension of an electrochemically active material (anodic or cathodic particles or particulates), and optionally an electronically conductive material (e.g., carbon) in a non-aqueous liquid electrolyte. Said another way, the active electrode particles and conductive particles are co-suspended in an electrolyte to produce a semi-solid electrode. Examples of battery architectures utilizing semi-solid suspensions are described in U.S. Patent Publication No. 2022/0238923 (“the '923 publication”), filed Jan. 21, 2022 and titled “Production of Semi-Solid Electrodes Via Addition of Electrolyte to Mixture of Active Material, Conductive Material, and Electrolyte Solvent,” and Provisional Patent Application No. 63/354,056 (“the '056 application”), filed Jun. 21, 2022 and titled “Electrochemical Cells with High-Viscosity Semi-solid Electrodes, and Methods of Making the Same,” the entire disclosures of which are hereby incorporated by reference.

In some embodiments, power management systems described herein can include any of the aspects described in U.S. Pat. No. 10,153,651 (“the '651 patent”), filed Oct. 9, 2015, and titled, “Systems and Methods for Battery Charging,” the disclosure of which is hereby incorporated by reference in its entirety. In some embodiments, battery management systems described herein can include any of the aspects described in U.S. patent application Ser. No. 17/743,631 (“the '631 application”), filed Nov. 20, 2020, and titled, “Electrochemical Cells Connected in Series in a Single Pouch and Methods of Making the Same,” the disclosure of which is hereby incorporated by reference in its entirety.

As used in this specification, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

The term “substantially” when used in connection with “cylindrical,” “linear,” and/or other geometric relationships is intended to convey that the structure so defined is nominally cylindrical, linear or the like. As one example, a portion of a support member that is described as being “substantially linear” is intended to convey that, although linearity of the portion is desirable, some non-linearity can occur in a “substantially linear” portion. Such non-linearity can result from manufacturing tolerances, or other practical considerations (such as, for example, the pressure or force applied to the support member). Thus, a geometric construction modified by the term “substantially” includes such geometric properties within a tolerance of plus or minus 5% of the stated geometric construction. For example, a “substantially linear” portion is a portion that defines an axis or center line that is within plus or minus 5% of being linear.

As used herein, the term “set” and “plurality” can refer to multiple features or a singular feature with multiple parts. For example, when referring to a set of electrodes, the set of electrodes can be considered as one electrode with multiple portions, or the set of electrodes can be considered as multiple, distinct electrodes. Additionally, for example, when referring to a plurality of electrochemical cells, the plurality of electrochemical cells can be considered as multiple, distinct electrochemical cells or as one electrochemical cell with multiple portions. Thus, a set of portions or a plurality of portions may include multiple portions that are either continuous or discontinuous from each other. A plurality of particles or a plurality of materials can also be fabricated from multiple items that are produced separately and are later joined together (e.g., via mixing, an adhesive, or any suitable method).

As used herein, the term “semi-solid” refers to a material that is a mixture of liquid and solid phases, for example, such as a particle suspension, a slurry, a colloidal suspension, an emulsion, a gel, or a micelle.

As used herein, the terms “activated carbon network” and “networked carbon” relate to a general qualitative state of an electrode. For example, an electrode with an activated carbon network (or networked carbon) is such that the carbon particles within the electrode assume an individual particle morphology and arrangement with respect to each other that facilitates electrical contact and electrical conductivity between particles and through the thickness and length of the electrode. Conversely, the terms “unactivated carbon network” and “unnetworked carbon” relate to an electrode wherein the carbon particles either exist as individual particle islands or multi-particle agglomerate islands that may not be sufficiently connected to provide adequate electrical conduction through the electrode.

As used herein, the terms “energy density” and “volumetric energy density” refer to the amount of energy (e.g., MJ) stored in an electrochemical cell per unit volume (e.g., L) of the materials included for the electrochemical cell to operate such as, the electrodes, the separator, the electrolyte, and the current collectors. Specifically, the materials used for packaging the electrochemical cell are excluded from the calculation of volumetric energy density.

As used herein, the terms “high-capacity materials” or “high-capacity anode materials” refer to materials with irreversible capacities greater than 300 mAh/g that can be incorporated into an electrode in order to facilitate uptake of electroactive species. Examples include tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

As used herein, the term “composite high-capacity electrode layer” refers to an electrode layer with both a high-capacity material and a traditional anode material, e.g., a silicon-graphite layer.

As used herein, the term “solid high-capacity electrode layer” refers to an electrode layer with a single solid phase high-capacity material, e.g., sputtered silicon, tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

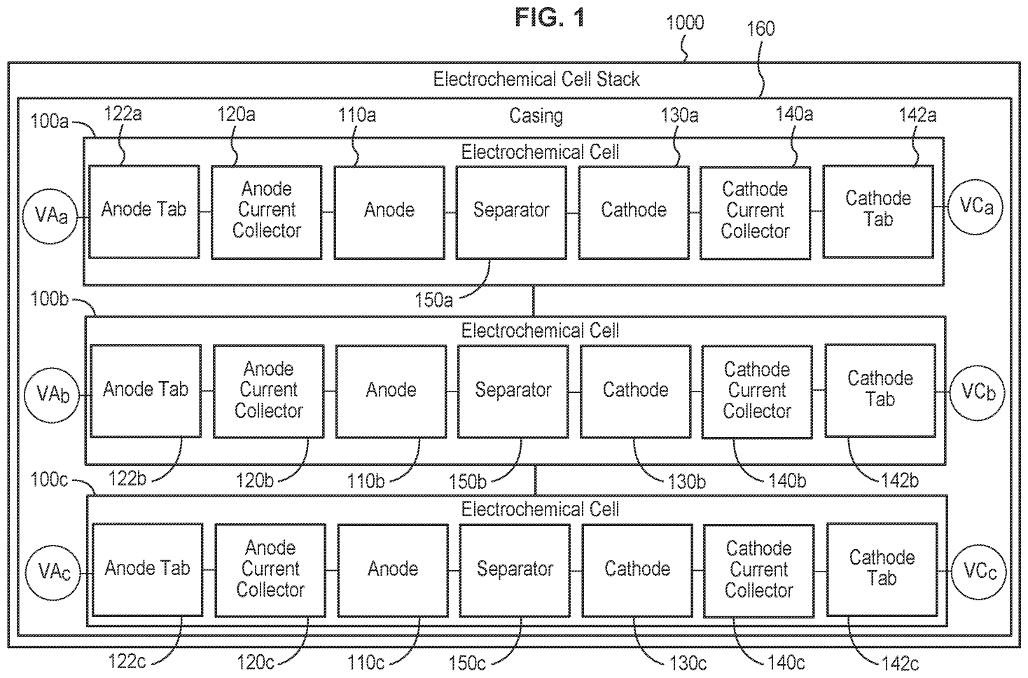

FIG. 1 is a block diagram of an electrochemical cell stack 1000, according to an embodiment. As shown, the electrochemical cell stack 1000 includes electrochemical cells 100a, 100b, 100c (collectively referred to as electrochemical cells 100). However, any number of electrochemical cells may be included in an electrochemical cell stack. In some embodiments, a number of electrochemical cells in each stack 1000 may be in a range of about 2 to about 100, inclusive (e.g., about 3, about 4, about 5, about 10, about 15, about 20, about 25, about 30, about about 40, about 45, about 50, about 55, about 60, about 65, about 70, about 75, about 80, about about 90, about 95, or about 100 electrochemical cells, inclusive of all ranges and values therebetween).

The electrochemical cells 100 include anodes 110a, 110b, 110c (collectively referred to as anodes 110) disposed on anode current collectors 120a, 120b, 120c (collectively referred to as anode current collectors 120), cathodes 130a, 130b, 130c (collectively referred to as cathodes 130) disposed on cathode current collectors 140a, 140b, 140c (collectively referred to as cathode current collectors 140), and separators 150a, 150b, 150c (collectively referred to as separators 150) disposed between the anodes 110 and the cathodes 130. The anode current collectors 120 include anode tabs 122a, 122b, 122c (collectively referred to as anode tabs 122). The cathode current collectors 140 include cathode tabs 142a, 142b, 142c (collectively referred to as cathode tabs 142). Anode voltage measurement points VAₐ, VA_{b}, VA_{c} measure voltage at the anode tab 122a, the anode tab 122b, and the anode tab 122c, respectively. Cathode voltage measurements points VCₐ, VC_{b}, VC_{c} measure voltage at the cathode tab 142a, the cathode tab 142b, and the cathode tab 142c, respectively. As shown, each of the electrochemical cells 100 is disposed in a casing 160. In some embodiments, each of the electrochemical cells 100 can be placed in an individual casing.

The electrochemical cell stack 1000 is equipped to measure voltage at each of the anode tabs 122 and each of the cathode tabs 142. Measuring voltage difference from one anode to another anode or from one cathode to another cathode can aid in identifying problematic cells. For example, in a lithium-ion battery pack containing multiple cells in electrical series, cell voltages can be individually monitored to ensure they do not exceed set limits during charge or discharge. Because of cell-to-cell variation, cells can also be periodically balanced to ensure voltages do not significantly diverge, as this would hamper overall performance. Balancing can include adding or removing electrical charge from one of the electrochemical cells 100 to bring it in-line with other electrochemical cells 100 within the electrochemical cell stack 1000. In some embodiments, the anode tabs 122 and/or the cathode tabs 142 can penetrate the casing 160 such that the anode tabs 122 and/or the cathode tabs 142 can be monitored externally. In some embodiments, the anode tabs 122 and/or the cathode tabs 142 can be electrically connected to external anode tabs and/or external cathode tabs (not shown) so that the voltage can be monitored externally.

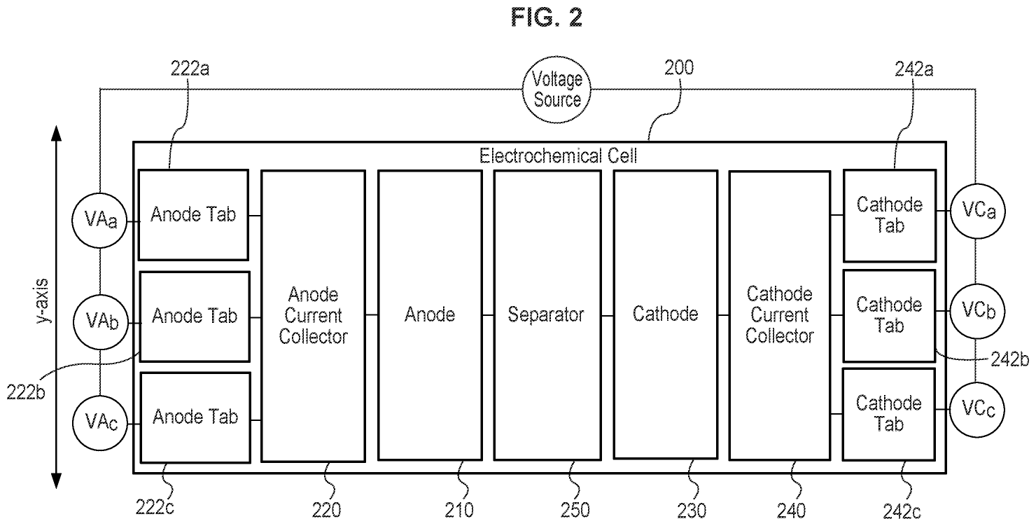

FIG. 2 is a block diagram of an electrochemical cell 200, according to an embodiment. As shown, the electrochemical cell 200 includes an anode 210 disposed on an anode current collector 220, a cathode 230 disposed on a cathode current collector 240, and a separator 250 disposed between the anode 210 and the cathode 230. Anode tabs 222a, 222b, 222c (collectively referred to anode tabs 222) are coupled to or incorporated into the anode current collector 220 and cathode tabs 242a, 242b, 242c (collectively referred to as cathode tabs 242) are coupled to or incorporated into the cathode current collector 240. In some embodiments, the anode 210, the anode current collector 220, the anode tabs 222, the cathode 230, the cathode current collector 240, the cathode tabs 242, and the separator 250 can be the same or substantially similar to the anodes 110, the anode current collectors 120, the anode tabs 122, the cathodes 130, the cathode current collectors 140, the cathode tabs 142, and the separator 150, as described above with reference to FIG. 1. Thus, certain aspects of the anode 210, the anode current collector 220, the anode tabs 222, the cathode 230, the cathode current collector 240, the cathode tabs 242, and the separator 250 are not described in greater detail herein.

The electrochemical cell 200 includes anode voltage measurement points VAₐ, VA_{b}, VA_{c} (collectively referred to as cathode voltage measurement points VA) positioned on the anode tabs 222 and cathode voltage measurement points VCₐ, VC_{b}, VC_{c} (collectively referred to as cathode voltage measurement points VC) positioned on the cathode tabs 242. In other words, the voltage can be measured at multiple locations along the anode 210 and the cathode 230. As noted above, cells can be periodically balanced to ensure voltages do not significantly diverge across a stack. In cells with large-area electrodes, intra-electrode voltage gradients can exist, which affect the voltage measured at any single reference point. Intra-electrode voltage gradients can reduce the effectiveness of balancing and state-of-health monitoring algorithms. Intra-electrode voltage gradients can also cause intra-electrode temperature gradients and reduced cycling efficiency. Including multiple anode voltage measurement points VA and multiple cathode voltage measurement points VC for each cell 200 in a stack enables measurement of intra-electrode voltage gradients directly, rather than reliance on an estimation of the intra-electrode voltage gradient from algorithms, thereby increasing accuracy of balancing and monitoring methods.

As shown, the anode current collector 220 includes three anode tabs 222 and three voltage measurement points VA. In some embodiments, the anode current collector 220 can include at least about 2, at least about 3, at least about 4, at least about 5, at least about 6, at least about 7, at least about 8, at least about 9, at least about 10, at least about 15, at least about 20, at least about at least about 30, at least about 35, at least about 40, at least about 45, at least about 50, at least about 55, at least about 60, at least about 65, at least about 70, at least about 75, at least about 80, at least about 85, at least about 90, or at least about 95 anode tabs 222 and/or voltage measurement points VA. In some embodiments, the anode current collector 220 can include no more than about 100, no more than about 95, no more than about 90, no more than about 85, no more than about no more than about 75, no more than about 70, no more than about 65, no more than about 60, no more than about 55, no more than about 50, no more than about 45, no more than about 40, no more than about 35, no more than about 30, no more than about 25, no more than about 20, no more than about 15, no more than about 10, no more than about 9, no more than about 8, no more than about 7, no more than about 6, no more than about 5, no more than about 4, or no more than about 3 anode tabs 222 and/or voltage measurement points VA. Combinations of the above-referenced numbers of anode tabs 222 and voltage measurement points VA are also possible (e.g., at least about 2 and no more than about 100 or at least about 4 and no more than about 30), inclusive of all values and ranges therebetween. In some embodiments, the anode current collector 220 can include about 2, about 3, about 4, about 5, about 6, about 7, about 8, about 9, about 10, about 15, about 20, about 25, about 30, about 35, about 40, about 45, about 50, about 55, about 60, about 65, about 70, about 75, about 80, about 85, about 90, about 95, or about 100 anode tabs 222 and/or voltage measurement points VA.

As shown, the cathode current collector 240 includes three cathode tabs 242 and three voltage measurement points VC. In some embodiments, the cathode current collector 240 can include at least about 2, at least about 3, at least about 4, at least about 5, at least about 6, at least about 7, at least about 8, at least about 9, at least about 10, at least about 15, at least about 20, at least about 25, at least about 30, at least about 35, at least about 40, at least about 45, at least about at least about 55, at least about 60, at least about 65, at least about 70, at least about 75, at least about 80, at least about 85, at least about 90, or at least about 95 cathode tabs 242 and/or voltage measurement points VC. In some embodiments, the cathode current collector 240 can include no more than about 100, no more than about 95, no more than about 90, no more than about 85, no more than about 80, no more than about 75, no more than about 70, no more than about 65, no more than about 60, no more than about 55, no more than about 50, no more than about 45, no more than about 40, no more than about 35, no more than about 30, no more than about 25, no more than about 20, no more than about 15, no more than about 10, no more than about 9, no more than about 8, no more than about 7, no more than about 6, no more than about 5, no more than about 4, or no more than about 2 cathode tabs 242 and/or voltage measurement points VC. Combinations of the above-referenced numbers of anode tabs 242 and voltage measurement points VC are also possible (e.g., at least about 2 and no more than about 100 or at least about 4 and no more than about 30), inclusive of all values and ranges therebetween. In some embodiments, the cathode current collector 240 can include about 2, about 3, about 4, about 5, about 6, about 7, about 8, about 9, about 10, about 15, about 20, about 25, about 30, about 35, about 40, about 45, about about 55, about 60, about 65, about 70, about 75, about 80, about 85, about 90, about 95, or about 100 cathode tabs 242 and/or voltage measurement points VC.

As shown, the voltage source is provided from above the electrochemical cell 200. In other words, the voltage source can be closer in proximity to the anode tab 222a than the anode tab 222c. During discharge, voltage at VC_{c}>voltage at VC_{b}>voltage at VCₐ. During charge, voltage at VC_{c}<voltage at VC_{b}<voltage at VCₐ. During charge, voltage at VA_{c}<voltage at VA_{b}<voltage at VAₐ. During discharge, voltage at VA_{c}>voltage at VA_{b}>voltage at VAₐ. The length of electrochemical cell 200 extends along a y-axis direction, as depicted in FIG. 2. The “sense voltage” can be defined as the difference between VC and VA at a reference point along the length (the y-axis) of the electrochemical cell 200. The “sense voltage” can be measured at various reference points along the length (the y-axis) of electrochemical cell 200 (e.g., VAₐ-VCₐ or VA_{b}-VC_{b}).

During or directly after discharge, the sense voltage is lower than the average cell voltage. During or directly after charge, the sense voltage is higher than average cell voltage. This effect becomes stronger given any of the following conditions: high rates of charge or discharge, high surface area electrodes (as the point of measuring the sense voltage becomes more distant from the voltage source), low temperature charge or discharge, high resistance cell designs (i.e., low power), and aged cells with increased internal resistance. Benefits of monitoring the sense voltage include: (1) enhanced state-of-health monitoring, (2) elimination of the need to pause balancing function to take a voltage measurement, and (3) early detection of performance issues in cells (e.g., uneven aging in electrodes or uneven temperature distribution across electrode area). Evaluation of voltage differentials in the active material across the face of the electrochemical cell allows tracking of changes in the active material over time (e.g., increased cell impedance, reduced cell capacity, etc.). Multiple anode tabs 222 and cathode tabs 242 enable measurement of these changes in the active material in real time. When trying to detect faulty cells, measuring the sense voltage from a tab that is also used to balance or power the electrochemical cell 200 is disadvantageous because of current flow through the tab, and the presence of active material in close proximity to the tab, which may negatively impact measurements collected (e.g., causing a voltage offset to the measurements). Voltage offset occurs because current flow through the tab material may generate an additional voltage drop and have a polarizing effect on the active material in the cathode. Inclusion of multiple anode tabs 222 and cathode tabs 242 addresses this disadvantage because the sense voltage can be measured from a tab through which current does not flow.

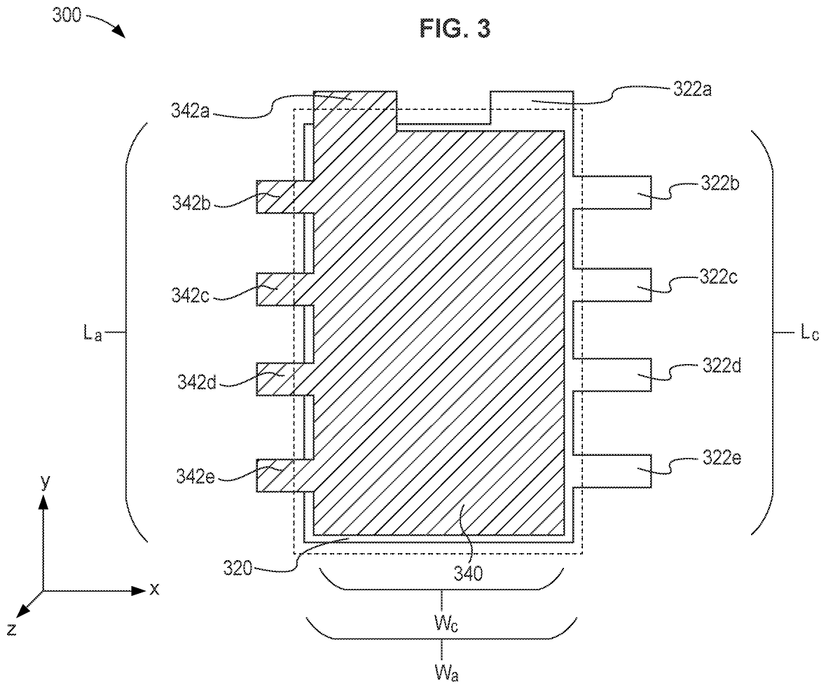

FIG. 3 shows an electrochemical cell 300, according to an embodiment. As shown, the electrochemical cell 300 includes an anode current collector 320 with anode tabs 322a, 322b, 322c, 322d, 322e (collectively referred to as anode tabs 322) and a cathode current collector 340 with cathode tabs 342a, 342b, 342c, 342d, 342e (collectively referred to as cathode tabs 342). The electrochemical cell 300 also includes an anode, a cathode, and a separator (not shown). In some embodiments, the anode current collector 320, the anode tabs 322, the cathode current collector 340, and the cathode tabs 342 can be the same or substantially similar to the anode current collector 220, the anode tabs 222, the cathode current collector 240, and the cathode tabs 242, as described above with reference to FIG. 2. Thus, certain aspects of the anode current collector 320, the anode tabs 322, the cathode current collector 340, and the cathode tabs 342 are not described in greater detail herein.

Axes are depicted in FIG. 3 for structural clarity. As shown, the anode current collector 320 has a length Lₐ and a width Wₐ. As shown, the cathode current collector 340 has a length L_{c} and a width W_{c}. The length Lₐ and the length L_{c} are defined as a distance the anode current collector 320 and a distance the cathode current collector 340 extend along the y-axis, respectively. The width Wₐ and the width We are defined as a distance the anode current collector 320 a distance the cathode current collector 340 extend along the x-axis, respectively. The electrochemical cell 300 includes a proximal end along the y-axis. As shown, the anode tab 322a and the cathode tab 342a are located at the proximal end of the y-axis. The electrochemical cell 300 includes a distal end opposite the proximal end.

In some embodiments, Lₐ and/or L_{c} can be at least about 1 cm, at least about 2 cm, at least about 3 cm, at least about 4 cm, at least about 5 cm, at least about 6 cm, at least about 7 cm, at least about 8 cm, at least about 9 cm, at least about 10 cm, at least about 20 cm, at least about 30 cm, at least about 40 cm, at least about 50 cm, at least about 60 cm, at least about 70 cm, at least about 80 cm, or at least about 90 cm. In some embodiments, Lₐ and/or L_{c} can be no more than about 1 m, no more than about 90 cm, no more than about 80 cm, no more than about 70 cm, no more than about 60 cm, no more than about 50 cm, no more than about 40 cm, no more than about cm, no more than about 20 cm, no more than about 10 cm, no more than about 9 cm, no more than about 8 cm, no more than about 7 cm, no more than about 6 cm, no more than about 5 cm, no more than about 4 cm, no more than about 3 cm, or no more than about 2 cm. Combinations of the above-referenced lengths are also possible (e.g., at least about 1 cm and no more than about 1 m or at least about 3 cm and no more than about 10 cm), inclusive of all values and ranges therebetween. In some embodiments, Lₐ and/or L_{c} can be about 1 cm, about 2 cm, about 3 cm, about 4 cm, about 5 cm, about 6 cm, about 7 cm, about 8 cm, about 9 cm, about 10 cm, about 20 cm, about 30 cm, about 40 cm, about 50 cm, about 60 cm, about 70 cm, about 80 cm, about 90 cm, or about 1 m.

In some embodiments, Wₐ and/or W_{c} can be at least about 5 mm, at least about 6 mm, at least about 7 mm, at least about 8 mm, at least about 9 mm, at least about 1 cm, at least about 2 cm, at least about 3 cm, at least about 4 cm, at least about 5 cm, at least about 6 cm, at least about 7 cm, at least about 8 cm, at least about 9 cm, at least about 10 cm, at least about 20 cm, at least about 30 cm, or at least about 40 cm. In some embodiments, Wₐ and/or W_{c} can be no more than about 50 cm, no more than about 40 cm, no more than about 30 cm, no more than about 20 cm, no more than about 10 cm, no more than about 9 cm, no more than about 8 cm, no more than about 7 cm, no more than about 6 cm, no more than about 5 cm, no more than about 4 cm, no more than about 3 cm, no more than about 2 cm, no more than about 1 cm, no more than about 9 mm, no more than about 8 mm, no more than about 7 mm, or no more than about 6 mm. Combinations of the above-referenced widths are also possible (e.g., at least about 5 mm and no more than about cm or at least about 2 cm and no more than about 10 cm), inclusive of all values and ranges therebetween. In some embodiments, Wₐ and/or W_{c} can be about 5 mm, about 6 mm, about 7 mm, about 8 mm, about 9 mm, about 1 cm, about 2 cm, about 3 cm, about 4 cm, about 5 cm, about 6 cm, about 7 cm, about 8 cm, about 9 cm, about 10 cm, about 20 cm, about 30 cm, about 40 cm, or about 50 cm.

As shown, the anode current collector 320 includes 5 anode tabs 322. In some embodiments, the anode current collector 320 can include at least about 2, at least about 3, at least about 4, at least about 5, at least about 6, at least about 7, at least about 8, at least about 9, at least about 10, at least about 15, at least about 20, at least about 25, at least about 30, at least about 35, at least about 40, at least about 45, at least about 50, at least about 55, at least about 60, at least about 65, at least about 70, at least about 75, at least about 80, at least about 85, at least about 90, or at least about 95 anode tabs 322. In some embodiments, the anode current collector 320 can include no more than about 100, no more than about 95, no more than about 90, no more than about 85, no more than about 80, no more than about 75, no more than about 70, no more than about 65, no more than about 60, no more than about 55, no more than about 50, no more than about 45, no more than about 40, no more than about 35, no more than about 30, no more than about 25, no more than about 20, no more than about 15, no more than about 10, no more than about 9, no more than about 8, no more than about 7, no more than about 6, no more than about 5, no more than about 4, or no more than about 3 anode tabs 322. Combinations of the above-referenced numbers of anode tabs 322 are also possible (e.g., at least about 2 and no more than about 100 or at least about 5 and no more than about 50), inclusive of all values and ranges therebetween. In some embodiments, the anode current collector 320 can include about 2, about 3, about 4, about 5, about 6, about 7, about 8, about 9, about 10, about 15, about 20, about 25, about 30, about 35, about 40, about 45, about 50, about 55, about 60, about 65, about 70, about 75, about 80, about 85, about 90, about 95, or about 100 anode tabs 322.

As shown, the cathode current collector 340 includes 5 cathode tabs 342. In some embodiments, the cathode current collector 340 can include at least about 2, at least about 3, at least about 4, at least about 5, at least about 6, at least about 7, at least about 8, at least about 9, at least about 10, at least about 15, at least about 20, at least about 25, at least about 30, at least about 35, at least about 40, at least about 45, at least about 50, at least about 55, at least about 60, at least about 65, at least about 70, at least about 75, at least about 80, at least about 85, at least about 90, or at least about 95 cathode tabs 342. In some embodiments, the cathode current collector 340 can include no more than about 100, no more than about 95, no more than about 90, no more than about 85, no more than about 80, no more than about 75, no more than about 70, no more than about 65, no more than about 60, no more than about 55, no more than about 50, no more than about 45, no more than about 40, no more than about 35, no more than about 30, no more than about 25, no more than about 20, no more than about 15, no more than about 10, no more than about 9, no more than about 8, no more than about 7, no more than about 6, no more than about 5, no more than about 4, or no more than about 3 cathode tabs 342. Combinations of the above-referenced numbers of cathode tabs 342 are also possible (e.g., at least about 2 and no more than about 100 or at least about 5 and no more than about 50), inclusive of all values and ranges therebetween. In some embodiments, the cathode current collector 340 can include about 2, about 3, about 4, about 5, about 6, about 7, about 8, about 9, about 10, about 15, about 20, about 25, about 30, about 35, about 40, about 45, about 50, about 55, about 60, about 65, about 70, about 75, about 80, about 85, about 90, about 95, or about 100 cathode tabs 342.

As shown, the cathode current collector 340 includes one cathode tab 342a located along W_{c} and extending outward (e.g., in a positive y-direction) from the proximal end of the electrochemical cell 300, and four cathode tabs 342b, 342c, 342d, 342e located along L_{c} and extending outward (e.g., in a negative x-direction) from the first horizontal side of the electrochemical cell 300. In some embodiments, the cathode current collector 340 can include multiple cathode tabs 342 along W_{c} and extending in outward. As shown, the anode current collector 320 includes one anode tab 322a located along Wₐ and extending outward (e.g., in a positive y-direction) from the proximal end of the electrochemical cell 300, and four anode tabs 322b, 322c, 322d, 322e located along Lₐ and extending outward (e.g., in a positive x-direction) from the second horizontal side of the electrochemical cell 300. In some embodiments, the anode current collector 320 can include multiple anode tabs 322 along Wₐ extending outward from the proximal end of the electrochemical cell 300.

In some embodiments, the distance between each of the cathode tabs 342a, 342b, 342c, 342d, 342e and the distance between each of the anode tabs 322a, 322b, 322c, 322d, 322e may be at least about 0.5 cm, at least about 1 cm, at least about 1.5 cm, at least about 2 cm, at least about 2.5 cm, or at least about 3 cm. In some embodiments, the distance between each of the cathode tabs 342 and the distance between each of the anode tabs 322 can be no more than about 5 cm, no more than about 4.5 cm, no more than about 4 cm, no more than about 3.5 cm, no more than about 3 cm, no more than about 2.5 cm, no more than about 2 cm, no more than about 1.5 cm, no more than about 1 cm. Combinations of the above-referenced distances are also possible, inclusive of all values and ranges therebetween.

In some embodiments, the cathode tabs 342 extending from the same side of the cathode current collector 340 (e.g., cathode tabs 342b, 342c, 342d, 342e) can be evenly spaced apart from each other. In some embodiments, the cathode tabs 342 extending from the same side of the cathode current collector 340 can be unevenly spaced or their spacing can be variable. In some embodiments, the anode tabs 322 extending from the same side of the anode current collector 320 (e.g., anode tabs 322b, 322c, 322d, 322e) can be evenly spaced apart from each other. In some embodiments, the anode tabs 322 extending from the same side of the anode current collector 320 can be unevenly spaced or their spacing can be variable.

In some embodiments, the anode tabs 322b, 322c, 322d, 322e can be aligned or substantially aligned with the cathode tabs 342b, 342c, 342d, 342e, respectively (i.e., along the y-axis). Any number of the anode tabs 322 can be aligned with any number of the cathode tabs 342. In other words, any number of the anode tabs 322 can be at the same or a substantially similar location along Lₐ or L_{c} to any number of the cathode tabs 342. In some embodiments, any of the anode tabs 322 can be within about 10%, within about 9%, within about 8%, within about 7%, within about 6%, within about 5%, within about 4%, within about 3%, within about 2%, or within about 1% of alignment along the y-axis to any of the cathode tabs 342.

The anode tabs 322 may provide multiple locations or reference points along the length Lₐ of the anode current collector 320, enabling anode voltage measurements at multiple locations or reference points of the anode current collector 320. The cathode tabs 342 may provide multiple locations or reference points along the length L_{c} of the cathode current collector 320, enabling cathode voltage measurements at multiple locations of the cathode current collector 340. The sense voltage (e.g., the difference between the cathode voltage and the anode voltage) may then be calculated at each of the multiple reference points. In some embodiments, the electrochemical cell 300 may include anode tabs 322 at multiple locations or reference points along the width Wₐ of the anode current collector 320. In some embodiments, the electrochemical cell 300 may include cathode tabs 342 at multiple locations or reference points along the width W_{c} of the cathode current collector 340. The multiple reference points at which anode and/or cathode voltage may be measured along both Lₐ and Wₐ enables detection of intra-electrode gradients along both the length of the electrochemical cell 300 (y-direction) and the width of the electrochemical cell 300 (x-direction). In some embodiments, the anode tab 322a and the cathode tab 342a can be used to perform a balancing function while simultaneously monitoring the cathode and anode voltage, thereby enabling the electrochemical cell 300 to be monitored without needing to pause the balancing function.

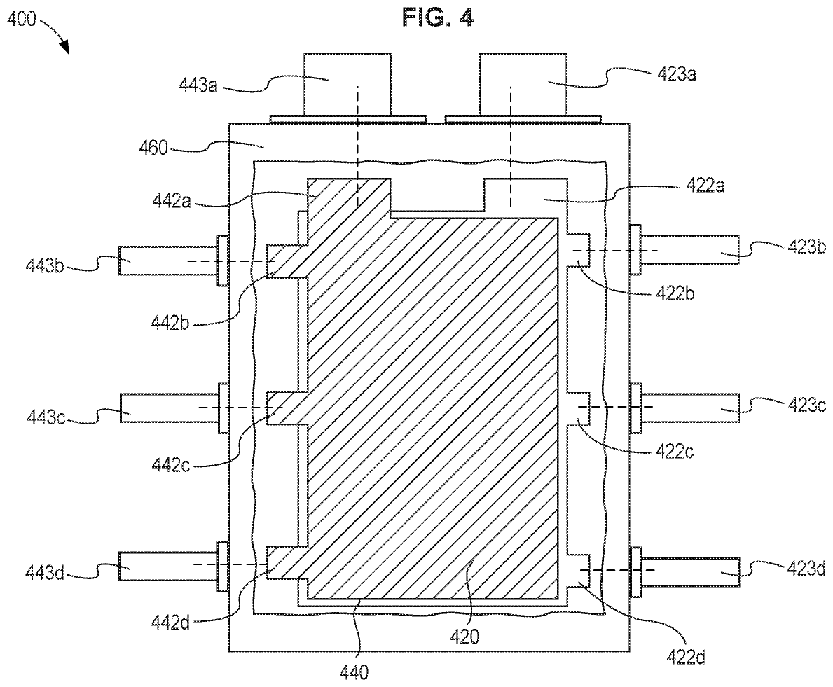

FIG. 4 shows an electrochemical cell 400, according to an embodiment. As shown, the electrochemical cell 400 includes an anode current collector 420 with anode tabs 422a, 422b, 422c, 422d (collectively referred to as anode tabs 422) and a cathode current collector 440 with cathode tabs 442a, 442b, 442c, 442d, 442e (collectively referred to as cathode tabs 442). The electrochemical cell 400 also includes an anode, a cathode, and a separator (not shown). The electrochemical cell 400 also includes a casing or housing 460 with external anode tabs 423a, 423b, 423c, 423d (collectively referred to as external anode tabs 423) and external cathode tabs 443a, 443b, 443c, 444d (collectively referred to as external cathode tabs 443) appended thereto. In some embodiments, the anode current collector 420, the anode tabs 422, the cathode current collector 440, and the cathode tabs 442 can be the same or substantially similar to the anode current collector 320, the anode tabs 322, the cathode current collector 340, and the cathode tabs 342, as described above with reference to FIG. 3. Thus, certain aspects of the anode current collector 420, the anode tabs 422, the cathode current collector 440, and the cathode tabs 442 are not described in greater detail herein.

The anode tabs 422 are electrically coupled to the external anode tabs 423. The cathode tabs 442 are electrically coupled to the external cathode tabs 443. In some embodiments, the external anode tabs 423 and the external cathode tabs 443 can be integrated into the casing 460. In other words, the external anode tabs 423 and the external cathode tabs 443 can be part of the same piece of material as the casing 460. The external anode tabs 423 and the external cathode tabs 443 allow for connections of voltage sources or voltage measurement devices at various points along the anode and/or cathode.

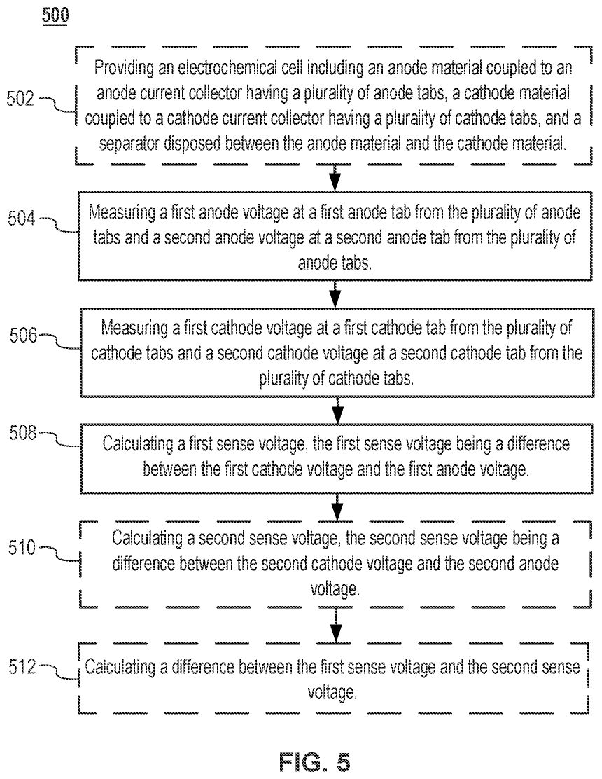

FIG. 5 is a schematic flow chart of a method 500 of monitoring health of an electrochemical cell. While described with respect to electrochemical cell 200 including the anode tabs 222, the cathode tabs 242, the anode current collector 220, and the cathode current collector 240, anode material 210, cathode material 240, and separator 250, the method 500 is equally applicable to any electrochemical cell including any anode tabs, cathode tabs, anode current collector, cathode current collector, anode material, cathode material, separator and/or any other components described herein. All such variants should be considered to be within the scope of this disclosure.

At step 502, the method 500 optionally includes providing an electrochemical cell 200 including an anode material 210 coupled to an anode current collector 220 having a plurality of anode tabs 222, a cathode material 230 coupled to a cathode current collector 240 having a plurality of cathode tabs 242, and a separator 250 disposed between the anode material 210 and cathode material 230. At step 504, a first anode voltage can be measured at a first anode tab from the plurality of anode tabs 222, and a second anode voltage can be measured at a second anode tab from the plurality of anode tabs 222. In some embodiments, a first anode tab and a second anode tab from the anode tabs 222 can be located on the same horizontal side of the electrochemical cell 200, the first anode tab being nearer to the proximal end of the electrochemical cell 200 than the second anode tab. At step 506, a first cathode voltage can be measured at a first cathode tab from the plurality of cathode tabs 242, and a second cathode voltage can be measured at a second cathode tab from the plurality of cathode tabs 242. In some embodiments, a first cathode tab and a second cathode tab from the cathode tabs 242 can be located on the same horizontal side of the electrochemical cell 200, the first cathode tab being nearer to the proximal end of the electrochemical cell 200 than the second cathode tab.

At step 508, the method 500 includes calculating a first sense voltage, the first sense voltage being a difference between the first cathode voltage and the first anode voltage. At optional step 510, the second sense voltage may be calculated, the second sense voltage being a difference between the second cathode voltage and the second anode voltage. At step 512, the method 500 may optionally include calculating the difference between the first sense voltage and the second sense voltage, thereby enabling detection and/or quantification of an intra-electrode gradient along the length (e.g., in the y-direction) of the electrochemical cell 200. In some embodiments, the method 500 may optionally include calculating a third sense voltage, the third sense voltage being a difference between a third cathode voltage measured at a third cathode tab located on the proximal end of the electrochemical cell 200 and a third anode voltage measured at a third anode tab on the proximal end of the electrochemical cell 200. The third sense voltage enabling detection and/or quantification of an intra-electrode gradient along the width (in the x-direction) of the electrochemical cell 200. In some embodiments, the method 500 may include balancing the electrochemical cell 200 via the third anode tab and the third cathode tab. For example, electrical charge can be added or removed from the electrochemical cell 200 via the third anode tab and/or the third cathode tab. In some embodiments, any one of the anode tabs 222 and any one of the cathode tabs 244 may be used to balance the electrochemical cell 200. In some embodiments, the electrochemical cell 200 may be disposed in a casing. In some embodiments, method 500 may include measuring anode voltages and cathode voltages via a plurality of external anode tabs and a plurality of external cathode tabs respectively such that the anode voltages and cathode voltages are measured external to the casing.

Various concepts may be embodied as one or more methods, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Put differently, it is to be understood that such features may not necessarily be limited to a particular order of execution, but rather, any number of threads, processes, services, servers, and/or the like that may execute serially, asynchronously, concurrently, in parallel, simultaneously, synchronously, and/or the like in a manner consistent with the disclosure. As such, some of these features may be mutually contradictory, in that they cannot be simultaneously present in a single embodiment. Similarly, some features are applicable to one aspect of the innovations, and inapplicable to others.

In addition, the disclosure may include other innovations not presently described. Applicant reserves all rights in such innovations, including the right to embodiment such innovations, file additional applications, continuations, continuations-in-part, divisional s, and/or the like thereof. As such, it should be understood that advantages, embodiments, examples, functional, features, logical, operational, organizational, structural, topological, and/or other aspects of the disclosure are not to be considered limitations on the disclosure as defined by the embodiments or limitations on equivalents to the embodiments. Depending on the particular desires and/or characteristics of an individual and/or enterprise user, database configuration and/or relational model, data type, data transmission and/or network framework, syntax structure, and/or the like, various embodiments of the technology disclosed herein may be implemented in a manner that enables a great deal of flexibility and customization as described herein.

All definitions, as defined and used herein, should be understood to control over dictionary definitions, definitions in documents incorporated by reference, and/or ordinary meanings of the defined terms.

As used herein, in particular embodiments, the terms “about” or “approximately” when preceding a numerical value indicates the value plus or minus a range of 10%. Where a range of values is provided, it is understood that each intervening value, to the tenth of the unit of the lower limit unless the context clearly dictates otherwise, between the upper and lower limit of that range and any other stated or intervening value in that stated range is encompassed within the disclosure. That the upper and lower limits of these smaller ranges can independently be included in the smaller ranges is also encompassed within the disclosure, subject to any specifically excluded limit in the stated range. Where the stated range includes one or both of the limits, ranges excluding either or both of those included limits are also included in the disclosure.

The phrase “and/or,” as used herein in the specification and in the embodiments, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the embodiments, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the embodiments, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the embodiments, shall have its ordinary meaning as used in the field of patent law.

As used herein in the specification and in the embodiments, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the embodiments, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

While specific embodiments of the present disclosure have been outlined above, many alternatives, modifications, and variations will be apparent to those skilled in the art. Accordingly, the embodiments set forth herein are intended to be illustrative, not limiting. Various changes may be made without departing from the spirit and scope of the disclosure. Where methods and steps described above indicate certain events occurring in a certain order, those of ordinary skill in the art having the benefit of this disclosure would recognize that the ordering of certain steps may be modified and such modification are in accordance with the variations of the invention. Additionally, certain of the steps may be performed concurrently in a parallel process when possible, as well as performed sequentially as described above. The embodiments have been particularly shown and described, but it will be understood that various changes in form and details may be made.

1. A method of operating an electrochemical cell included in an electrochemical cell stack having a plurality of electrochemical cells, each of the electrochemical cells included in the electrochemical cell stack including an anode material coupled to an anode current collector having a plurality of anode tabs, a cathode material coupled to a cathode current collector having a plurality of cathode tabs, and a separator disposed between the anode material and the cathode material, the method comprising:
measuring an anode voltage difference between a first anode tab from the plurality of anode tabs and a second anode tab from the plurality of anode tabs of the electrochemical cell;
measuring a cathode voltage difference between a first cathode tab from the plurality of cathode tabs and a second cathode tab from the plurality of cathode tabs of the electrochemical cell; and
balancing the electrochemical cell relative to the other electrochemical cells included in the electrochemical cell stack based at least on the values of the anode voltage difference and the cathode voltage difference.

2. The method of claim 1, wherein the first cathode tab and the first anode tab are each located at a proximal end of the electrochemical cell.

3. The method of claim 2, wherein a distance between the first anode tab and the second anode tab is within about 5% of the distance between the first cathode tab and the second cathode tab.

4. The method of claim 2, wherein the second cathode tab extends outward from a first horizontal side of the electrochemical cell and the second anode tab extends outward from a second horizontal side of the electrochemical cell, the second horizontal side opposing the first horizontal side.

5. The method of claim 1, wherein the cathode current collector and the anode current collector each have a length of at least about 5 cm.

6. The method of claim 1, wherein the electrochemical cell is disposed in a casing, the casing including a plurality of external anode tabs and a plurality of external cathode tabs such that the anode voltage difference and the cathode voltage difference are measured from outside of the casing.

7. A method of monitoring health of an electrochemical cell, the electrochemical cell including an anode material coupled to an anode current collector having a plurality of anode tabs, a cathode material coupled to a cathode current collector having a plurality of cathode tabs, and a separator disposed between the anode material and the cathode material, the method comprising:
measuring a first anode voltage at a first anode tab from the plurality of anode tabs and a second anode voltage at a second anode tab from the plurality of anode tabs;
measuring a first cathode voltage at a first cathode tab from the plurality of cathode tabs and a second cathode voltage at a second cathode tab from the plurality of cathode tabs;
calculating a first sense voltage, the first sense voltage being a difference between the first cathode voltage and the first anode voltage.

8. The method of claim 7, further comprising:
calculating a second sense voltage, the second sense voltage being a difference between the second cathode voltage and the second anode voltage.

9. The method of claim 8, further comprising:
calculating a difference between the first sense voltage and the second sense voltage.

10. The method of claim 7, wherein the first cathode tab and the first anode tab extend outward from a proximal end of the electrochemical cell.

11. The method of claim 10, wherein a distance between the first anode tab and the second anode tab is within about 5% of the distance between the first cathode tab and the second cathode tab.

12. The method of claim 10, wherein the second cathode tab extends outward from a first horizontal side of the electrochemical cell and the second anode tab extends outward from a second horizontal side of the electrochemical cell, the second horizontal side opposing the first horizontal side.

13. The method of claim 7, wherein the cathode current collector and the anode current collector each have a length of at least about 5 cm.

14. The method of claim 7, wherein the cathode current collector and the anode current collector each have a width of at least about 5 mm.

15. The method of claim 7, wherein the electrochemical cell is disposed in a casing, the casing including a plurality of external anode and a plurality of external cathode tabs such that the first anode voltage, the second anode voltage, the first cathode voltage, and the second cathode voltage are measured from outside of the casing.

16. An electrochemical cell, comprising:
an anode material coupled to an anode current collector;
a cathode material coupled to a cathode current collector;
a separator disposed between the anode material and the cathode material;
a plurality of anode tabs electrically connected to the anode current collector such that a first anode voltage can be measured at a first anode tab from the plurality of anode tabs and a second anode voltage can be measured at a second anode tab from the plurality of anode tabs; and
a plurality of cathode tabs electrically connected to the cathode current collector such that a first cathode voltage can be measured at a first cathode tab from the plurality of cathode tabs and a second cathode voltage can be measured at a second cathode tab from the plurality of cathode tabs.

17. The electrochemical cell of claim 16, wherein the first cathode tab and the first anode tab extend outward from a proximal end of the electrochemical cell.

18. The electrochemical cell of claim 17, wherein the plurality of cathode tabs excluding the first cathode tab extend outward from a first horizontal side of the electrochemical cell and the plurality of anode tabs excluding the first anode tab extend outward from a second horizontal side of the electrochemical cell, the second horizontal side opposing the first horizontal side.

19. The electrochemical cell of claim 18, wherein a distance between the first anode tab and a second anode tab is within about 5% of the distance between the first cathode tab and a second cathode tab.

20. The electrochemical cell of claim 16, wherein distances between each of the anode tabs are in a range of about 1 cm to about 3 cm, and distances between each of the cathode tabs are in a range of about 1 cm to about 3 cm.

21. The electrochemical cell of claim 16, wherein the cathode current collector and the anode current collector each have a length of at least about 5 cm.

22. The electrochemical cell of claim 16, wherein the cathode current collector and the anode current collector each have a width of at least about 5 mm.

23. The electrochemical cell of claim 17, wherein the electrochemical cell is disposed in a casing, the casing including a plurality of external anode tabs and a plurality of external cathode tabs such that the first anode voltage, the second anode voltage, the first cathode voltage, and the second cathode voltage can be measured from outside of the casing.

24. The electrochemical cell of claim 16, wherein a first voltage gradient is measurable along the width of the electrochemical cell and a second voltage gradient is measurable along the length of the electrochemical cell.
